(19) United States
(12) Patent Application Publication
(10) Pub. No.: US 2006/0046456 A1
(43) Pub. Date: Mar. 2, 2006

(54) Damascene process using different kinds of metals

(75) Inventor: Chul-wan An, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/204,469

(22) Filed: Aug. 15, 2005

(30) Foreign Application Priority Data
Aug. 25, 2004 (KR) 10-2004-0067111

(51) Int. Cl. H01L 21/44

(52) U.S. Cl. 438/597

(57) ABSTRACT

The present invention is directed to a damascene process using different kinds of metals is provided. An interlayer dielectric is formed to cover a semiconductor substrate. A contact hole is formed to expose the semiconductor substrate through the interlayer dielectric. A groove is formed to overlap the contact hole. A first barrier metal layer is conformally formed. A first seed layer is conformally formed. A first conductive layer is formed to fill a contact hole below the groove. A second conductive layer is formed to fill the groove. According to the damascene process, a CMP process for a tungsten layer is not needed such that total process cost is reduced and the overall general process is simplified.

### PRIORITY STATEMENT

This application claims priority of Korean Patent Application No. 2004-67111, filed on Aug. 25, 2004 in the Korean Intellectual Property Office, the contents of which are incorporated herein in their entirety by reference.

### BACKGROUND OF THE INVENTION

1. Field of the Invention

The present invention relates to a method of fabricating semiconductor devices and, more particularly, to a damascene process using different kinds of metals.

2. Description of Related Art

A conventional method for forming a contact plug and interconnection of a semiconductor device will now be described in brief. An interlayer dielectric is formed on a semiconductor substrate. The interlayer dielectric is patterned to form a contact hole. A tungsten layer of a superior burial property is stacked to fill the contact hole. A planarization process using chemical mechanical polishing (CMP) is performed, so that the tungsten layer remains only in the contact hole to form a contact plug. An inter-metal dielectric is stacked to form an interconnection groove exposing the contact plug. A copper layer of a low resistance and a superior reliability is stacked to fill the groove. The copper layer is planarized using CMP, so that the inter-metal dielectric is exposed and the copper layer remains in the groove to form an interconnection.

In a CMP process for forming a contact plug, it is hard to uniformly polish a wafer surface. For example, portions of high-density contact holes may be eroded partially during a CMP process. In this case, a photo margin decreases due to a step difference in a subsequent photolithographic process, which makes it hard to precisely form a photoresist pattern. Further, a CMP process is an expensive process because it uses expendables such as slurries. If a CMP process for forming a contact plug is omitted, the above-described problems would be solved. In view of the foregoing, a conventional dual damascene process using copper may be suggested. However, if the conventional dual damascene process is applied to a process for forming an interconnection and a contact which is in direct contact with a gate electrode, it is possible that free electrons of the copper are diffused to polysilicon of a gate electrode to cause various problems which degrade reliability of a semiconductor device.

### SUMMARY OF THE INVENTION

Exemplary embodiments of the present invention are directed to a dual damascene process using different kinds of metals. Since a CMP process for forming a contact plug is omitted in the dual damascene process according to the present invention, process cost is reduced and a general process is simplified to enhance reliability of a semiconductor device.

According to an aspect of the invention, an interlayer dielectric is formed to cover a semiconductor substrate. The interlayer dielectric is patterned to form a groove and a contact hole at a bottom of the groove to expose the semiconductor substrate. A first barrier metal is conformally formed. A first seed layer is conformally formed. A first conductive layer is selectively formed to fill the contact hole below the groove. A second conductive layer is formed to fill the groove.

In some embodiments of the present invention, the substrate may further include a gate electrode disposed on the substrate and an impurity implantation region disposed in the substrate at opposite sides adjacent to the gate electrode. The contact hole may be formed to expose the impurity implantation region. Alternatively, the contact hole may be formed to expose the gate electrode. The formation of the first conductive layer is selectively done using electroplating. Preferably, the first conductive layer is made of tungsten. Prior to the formation of the second conductive layer, a trimming process may be performed. After the trimming process is performed, a cleaning process may be performed prior to the formation of the second conductive layer. Preferably, the cleaning process is performed using fluoride acid. Following the selective formation of the first conductive layer, a second barrier metal may be conformally formed. Preferably, the second conductive layer is made of copper. Prior to the formation of the second conductive layer, a second seed layer may be conformally formed. The formation of the second seed layer may be done using electro-plating or metal organic chemical vapor deposition (MOCVD). Following the formation of the second conductive layer, a planarization process may be performed to expose the interlayer dielectric.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 through FIG. 6 are cross-sectional views illustrating a damascene process according to an embodiment of the present invention.

FIG. 7 is a cross-sectional view illustrating a damascene process according to another embodiment of the present invention.

FIG. 8 is a cross-sectional view illustrating a damascene process according to still another embodiment of the present invention.

### DETAILED DESCRIPTION OF THE INVENTION

The present invention will now be described more fully hereinafter with reference to the accompanying drawings, in which preferred embodiments of the invention are shown. It will be understood that when a layer is referred to as being “on” another layer or substrate, it can be directly on the other layer or substrate, or intervening layers may also be present.

(Embodiment 1)

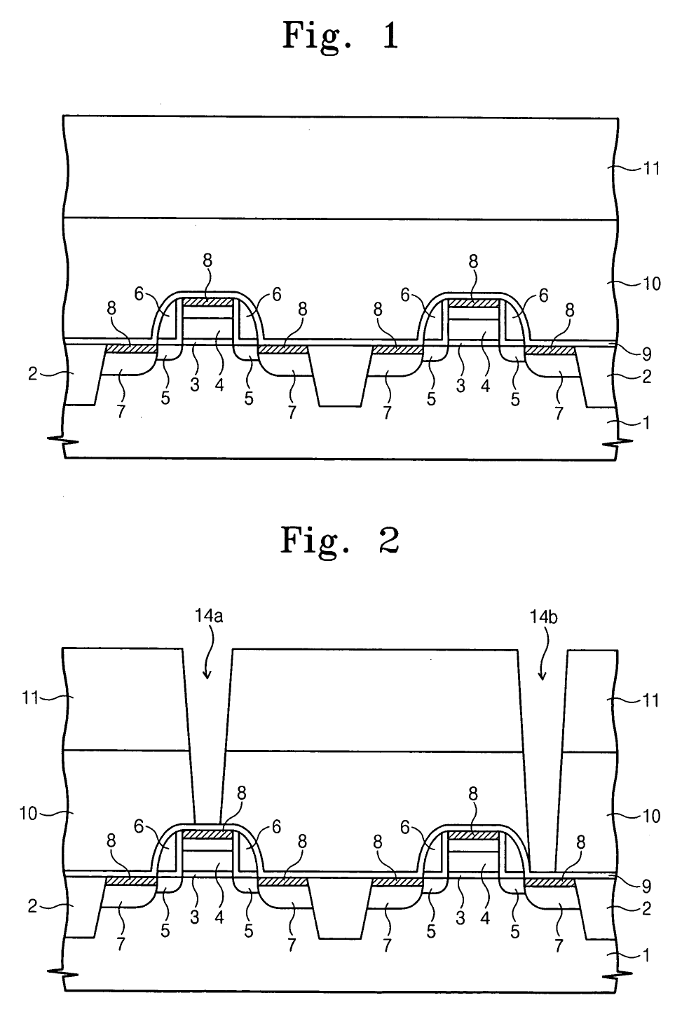

A damascene process according to a first embodiment of the present invention will now be described with reference to FIG. 1 through FIG. 6.

As illustrated in FIG. 1, device isolation layers 2 are formed in a semiconductor substrate to define active regions. A gate oxide layer 3 and a gate electrode 4 are sequentially formed on the active region. They are patterned to form a gate pattern. Using the gate pattern as an ion implanting mask, a lightly doped region 5 is formed in the substrate 1 at opposite sides adjacent to the gate pattern. A spacer 6 is formed to cover a sidewall of the gate pattern. Using the spacer 6 as an ion implanting mask, a heavily doped region 7 is formed in the substrate 1. After a metal layer is stacked, a heat treatment is conducted to form a silicide layer 8 on the gate electrode 4 and the heavily doped region 7. An unsilicided metal layer is removed. An etch-stop layer 9 is formed on an entire surface of the substrate 1. An interlayer dielectric 10 and an inter-metal dielectric 11 are sequentially formed on the etch-stop layer 9. The interlayer dielectric 10 and the inter-metal dielectric 11 are made of substances having an etch selectivity with respect to each other. Prior to the formation of the inter-metal dielectric 11, an etch-stop layer may be additionally formed on the interlayer dielectric 10.

As illustrated in FIG. 2, the inter-metal dielectric 11 and the interlayer dielectric 10 are successively patterned to form a first preliminary contact hole 14a exposing the etch-stop layer 9 over the gate electrode 4 and a second contact hole 14b exposing the etch-stop layer 9 over the heavily doped region 7.

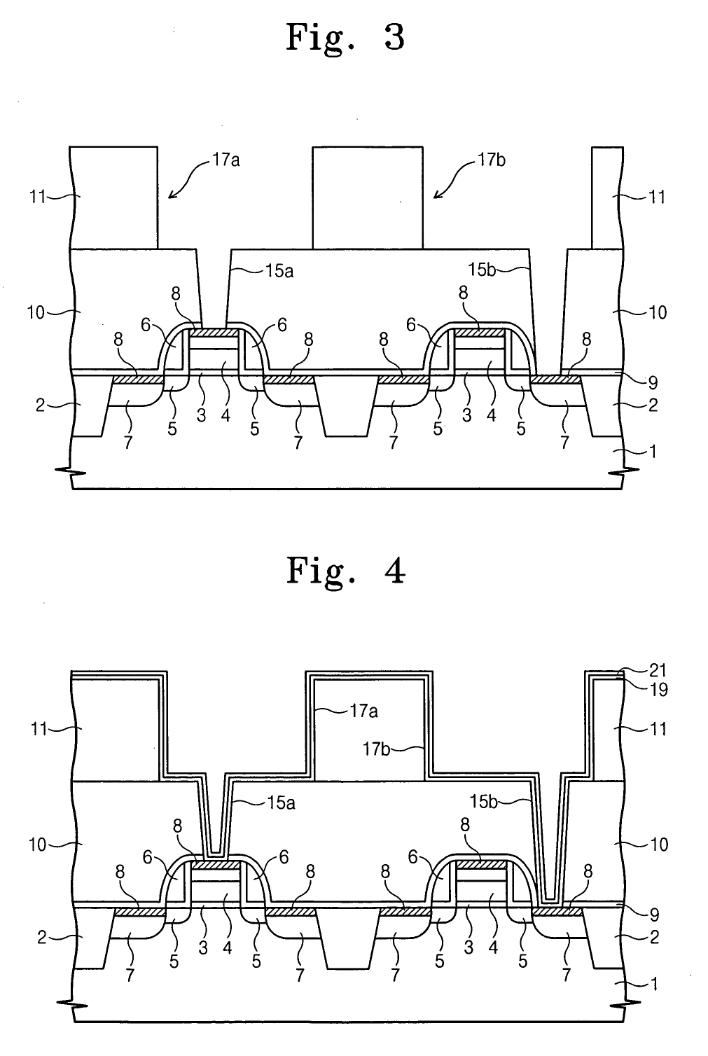

As illustrated in FIG. 3, the inter-metal dielectric 11 is patterned to form a first groove 17a overlapping a first contact hole 15a and a second groove 17b overlapping a second contact hole 15b. While the inter-metal dielectric 11 is etched, the etch-stop layer 9 and the interlayer dielectric 10 are not etched. The grooves 17a and 17b define an interconnection. The etch-stop layer 9 exposed by the preliminary contact holes 14a and 14b is removed to form the first and second contact holes 15a and 15b exposing the silicide layer 8. The first contact hole 15a is formed to expose the silicide layer 8 over the gate electrode 4, and the second contact hole 15b is formed to expose the silicide layer 8 over the heavily doped region 7.

There may be another method for forming the contact holes 15a. and 15b and the grooves 17a and 17b. After forming an interlayer dielectric that is a single layer, an upper portion of the interlayer dielectric is partially patterned to form a preliminary contact hole where the interlayer dielectric remains as much as a predetermined thickness. Using a mask to define a groove, the interlayer dielectric is etched to form grooves 17a and 17b. The interlayer dielectric disposed beneath the preliminary contact hole is also etched to expose an etch-stop layer 9. The exposed etch-stop layer 9 is removed to form the contact holes 15a and 15b.

There may be still another method for forming the contact holes 15a and 15b and the grooves 17a and 17b. Firstly, the inter-metal dielectric 11 is etched to form the grooves 17a and 17b. Using a photoresist pattern, the interlayer dielectric 10 and the etch-stop layer are successively etched to form the contact holes 15a and 15b.

As illustrated in FIG. 4, a first barrier metal layer 19 is conformally formed on an entire surface of a substrate 1 where the contact holes 15a and 15b and the grooves 17a and 17b are formed. The first barrier metal layer 19 may be made of at least one of titanium (Ti), titanium nitride (TiN), tantalum (Ta), and tantalum nitride (TaN). The formation of the first barrier metal layer 19 may be done using atomic layer deposition (ALD), chemical vapor deposition (CVD) and/or physical vapor deposition (PVD). A first seed layer 21 is conformally formed on the first barrier metal layer 19. Preferably, the first seed layer 21 is made of tungsten. The formation of the first seed layer 21 may be done using ALD and/or CVD.

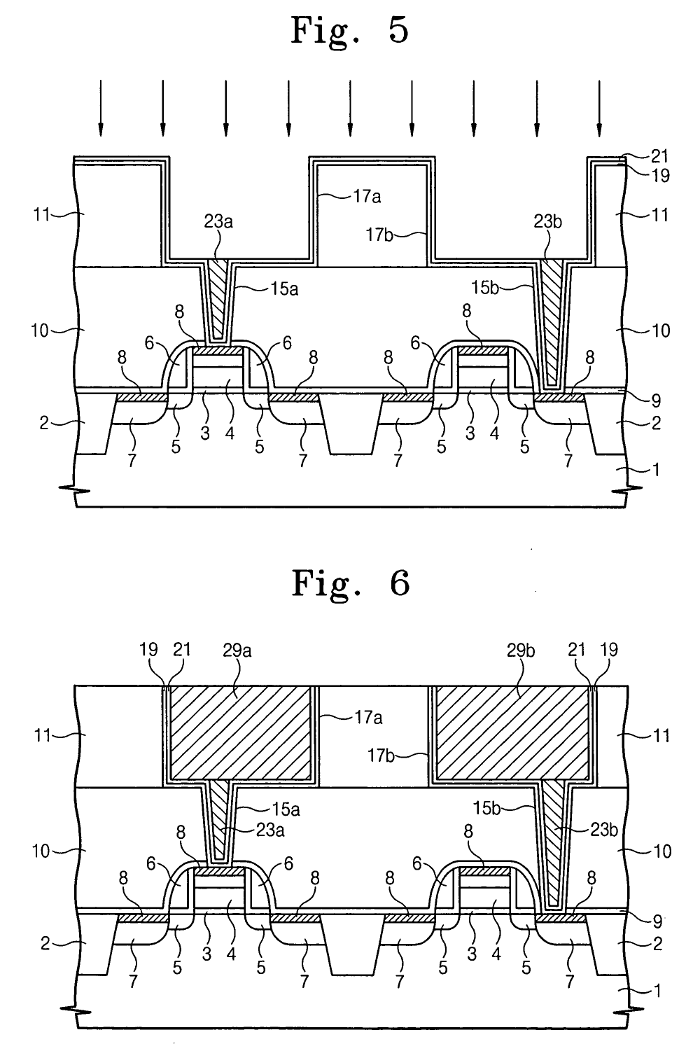

As illustrated in FIG. 5, under the state of FIG. 5, tungsten layers 23a and 23b for contact plugs are formed using electroplating to fill the contact holes 15a and 15b. The formation of the tungsten layers 23a and 23b is done by slowly filling the contact holes 15a and 15b from their bottoms. The method for forming the tungsten layers 23a and 23b using the electro-plating will now be described in detail. A substrate 1 including the first seed layer 21 is submerged in an electrolyte solution containing tungsten ions, which acts as a cathode. A voltage is applied to the cathode to selectively form a tungsten layer on the first seed layer 21. The electro-plating may be direct current (DC) plating using a 3-component additive, i.e., accelerator for accelerating filling of a fine groove such as a contact hole, a suppressor for suppressing deposition at an area that is not a fine groove, and a leveler for suppressing over-deposition such as overhang which may occur at an entrance of the contact hole. Due to the 3-component additive, the tungsten layers 23a and 23b are selectively formed in the contact holes 15a and 15b.

After filling the contact holes 15a and 15b with the tungsten layers 23a and 23b, a trimming process is performed in an arrow direction. The trimming process may be performed by a radio frequency (RF) etch using, for example, argon gas. The copper is chemically mechanically polished to expose the inter-metal dielectric 11 and to form interconnections 29a and 29b in the contact holes 15a and 15b respectively. The interconnections 29a and 29b are made of copper.

In the above-described method, the tungsten layers 23a and 23b constituting a contact plug are selectively formed in the contact holes 15a and 15b due to the electro-plating. Thus, a CMP process for a tungsten layer is not needed to reduce a total process cost and to simplify a general process.

(Embodiment 2)

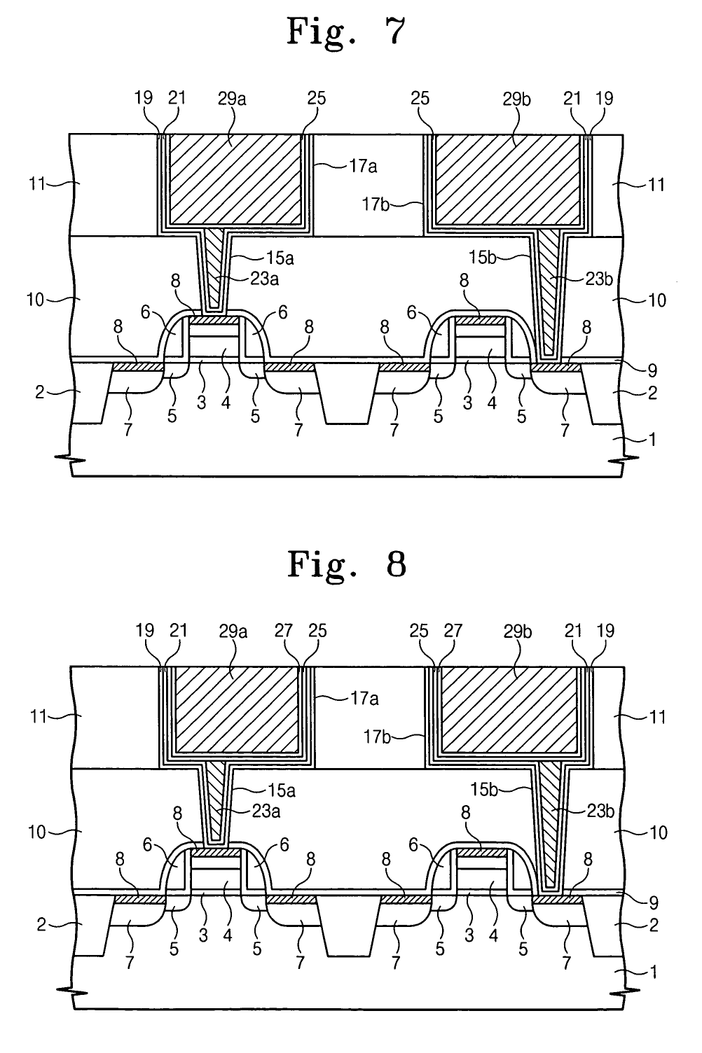

A damascene process according to another embodiment of the present invention will now be described with reference to FIG. 7.

As illustrated in FIG. 7, tungsten layers 23a and 23b for contact plugs are formed to fill contact holes 15a and 15b, as in FIG. 5. After a trimming process and a cleaning process are completed, a second barrier metal layer 25 is conformally formed on an entire surface of the structure. The second barrier metal layer 25 may be made of at least one of titanium (Ti), titanium nitride (TiN), tantalum (Ta), and tantalum nitride (TaN). The formation of the second barrier metal layer 25 may be done using atomic layer deposition (ALD), physical vapor deposition (PVD) and/or chemical vapor deposition (CVD). After a copper layer is formed using metal organic chemical vapor deposition (MOCVD), a planarization process is formed to interconnections 29a and 29b in the contact holes 15a and 15b, respectively. The interconnections 29a and 29b are made of copper. The second barrier metal layer 25 may be diffused to the tungsten layers 23a and 23b constituting the contact plug or may serve to prevent contamination of the tungsten layers 23a and 23b during the formation of the copper layer.

(Embodiment 3)

A damascene process according to still another embodiment of the present invention will now be described with reference to FIG. 8.

As illustrated in FIG. 8, tungsten layers 23a and 23b for contact plugs are formed to fill contact holes 15a and 15b, respectively. After a trimming process and a cleaning process are completed, a second barrier metal layer 25 is formed on an entire surface of the substrate 1. A second seed layer 27 is conformally formed on the second barrier metal layer 25. Preferably, the second seed layer 27 is made of copper. The formation of the second seed layer 27 may be done using atomic layer deposition (ALD) or metal organic chemical vapor deposition (MOCVD). A copper layer is formed on the second seed layer 27 using electro-plating to fill the grooves 17a and 17b. The copper layer is chemically mechanically planarized to form interconnections 29a and 29b, as shown in FIG. 8.

According to the inventive damascene process using different kinds of metals, a tungsten layer constituting a contact plug is selectively formed in a contact hole, and a copper layer for an interconnection is selectively formed in a groove overlapped with the contact hole, respectively. Thus, a CMP process for a tungsten layer is not needed to reduce a whole process cost and to simplify a whole process. Like a conventional method, a contact plug connected to a gate electrode is made of tungsten to enhance a reliability of a semiconductor device. Further, an interconnection is made of copper to enhance a speed of a semiconductor device.

In the above embodiments, electro-plating processes are performed twice to form a contact plug and an interconnection by using metals of different kinds. However, it will be apparent to those skilled in the art that electro-plating processes may be performed three or more times by using metals of different kinds to form contact plugs, pads and interconnects in a damascene hole having multi-layered recessed inner wall.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A damascene process comprising:
stacking an interlayer dielectric on a semiconductor substrate;
patterning the interlayer dielectric to form a groove and a contact at a bottom of the groove to expose the semiconductor substrate;
conformally forming a first barrier metal layer;
conformally forming a first seed layer;
selectively forming a first conductive layer to fill the contact hole; and
forming a second conductive layer to fill the groove.

2. The damascene process of claim 2, wherein the selective formation of the first conductive layer is done using electro-plating.

3. The damascene process of claim 1, wherein the first conductive layer comprises tungsten.

4. The damascene process of claim 2, further comprising performing a trimming process before the formation of the second conductive layer.

5. The damascene process of claim 4, wherein the trimming process comprises a radio frequency (RF) etch process using argon (Ar).

6. The damascene process of claim 4, further comprising performing a cleaning process after performing the trimming process.

7. The damascene process of claim 6, wherein the cleaning process is performed using hydrogen fluoride (HF).

8. The damascene process of claim 1, wherein the second conductive layer comprises copper.

9. The damascene process of claim 1, further comprising conformally forming a second seed layer before the formation of the second conductive layer,
wherein the formation of the second conductive layer is done using electro-plating.

10. The damascene process of claim 1, wherein the formation of the second conductive layer is done using metal organic chemical vapor deposition (MOCVD).

11. The damascene process of claim 9, further comprising conformally forming a second barrier metal layer after the formation of the first conductive layer.

12. The damascene process of claim 1, wherein the semiconductor substrate further includes a gate electrode disposed on the semiconductor substrate and an impurity implantation region disposed in the substrate at opposite sides adjacent to the gate electrode.

13. The damascene process of claim 1, wherein the semiconductor substrate further includes a gate electrode disposed on the substrate and an impurity implantation region disposed in the substrate at opposite sides adjacent to the gate electrode, the gate electrode being exposed during the formation of the contact hole.

14. The damascene process of claim 1, further comprising performing a planarization process to expose the interlayer dielectric after the formation of the second conductive layer.

15. The damascene process of claim 1, further comprising stacking an etch-stop layer on the semiconductor substrate before stacking the interlayer dielectric,
wherein the formation of the contact hole and the groove comprises:
patterning the interlayer dielectric to form a preliminary contact hole exposing the etch-stop layer over the semiconductor substrate;
patterning the interlayer dielectric to form a groove overlapping the preliminary contact hole; and
removing the etch-stop layer exposed by the preliminary contact hole to form a contact hole exposing the semiconductor substrate.

16. The damascene process of claim 1, wherein the formation of the groove and the contact hole comprises:
partially patterning an upper portion of the interlayer dielectric to form a groove for interconnection; and
patterning the interlayer dielectric beneath the groove to form a contact hole exposing the semiconductor substrate.
